(19) United States
(12) Patent Application Publication
(10) Pub. No.: US 2013/0015443 A1
(43) Pub. Date: Jan. 17, 2013

(54) SEMICONDUCTOR DEVICE AND MANUFACTURING METHOD THEREOF

(71) Applicants: YONGGEN HE, Beijing (CN); Bing Wu, Beijing (CN); Huanxin Liu, Beijing (CN)

(72) Inventors: YONGGEN HE, Beijing (CN); Bing Wu, Beijing (CN); Huanxin Liu, Beijing (CN)

(73) Assignee: Semiconductor Manufacturing International (Beijing) Corporation, Beijing (CN)

(21) Appl. No.: 13/291,088

(22) Filed: Nov. 7, 2011

(30) Foreign Application Priority Data
Jul. 15, 2011 (CN) 201110197676.0

(51) Int. Cl. H01L 29/78; H01L 21/336

(52) U.S. Cl. 257/57; 438/4; 257/E29.255; 257/E21.409

(57) ABSTRACT

A method for manufacturing a semiconductor device comprises: forming a recess in a substrate; implanting at the bottom of the recess to form an amorphous layer to a predetermined depth under the bottom of the recess; carrying out crystal orientation selective wet etching to form a Sigma shaped recess by use of the amorphous layer as a stopping layer. Through forming an amorphous layer by means of implantation which is used as a stopping layer in a subsequent wet etching, a Sigma shaped recess with a cuspate bottom is avoided, and a Sigma shaped recess having a planar bottom is obtained, which may further improve semiconductor device performance.

### CROSS-REFERENCES TO RELATED APPLICATIONS

This application claims priority to Chinese Patent Application No. 201110197676.0, filed on Jul. 25, 2011 and entitled “SEMICONDUCTOR DEVICE AND MANUFACTURING METHOD THEREOF”, which is incorporated herein by reference in its entirety.

### BACKGROUND OF THE INVENTION

1. Field of the Invention

The present invention relates to the field of semiconductor processes, and more particularly to a semiconductor device and its manufacturing method that is capable of providing a planar bottom in a Sigma shaped recess.

2. Description of the Related Art

In advanced CMOS techniques, an embedded SiGe (eSiGe) process is proposed in aim of increasing compress stress for a PMOS channel region to improve its carrier mobility, wherein source region or drain region is formed of embedded SiGe, such that a stress is applied to the channel region. Further, a technical scheme is proposed in which a sigma (E) (also called diamond) shaped recess is formed for filling with SiGe to enhance the effect of the applied stress, and thus improving PMOS device performance.

FIG. 1A to FIG. 1C schematically show sectional views of various steps in a process of forming a sigma-shaped recess in the prior art.

As shown in FIG. 1A, a substrate is provided with gates formed thereon, the crystal plane orientation of the surface of the substrate can be indicated as (100).

As shown in FIG. 1B, a U shaped recess (defined by points A, B, C and D) is formed in the substrate through dry etching. The crystal plane orientation of the bottom of the U shaped recess is also the same as (100), and the crystal plane orientation of the sidewalls of the U shaped recess can be indicated as (110). In a subsequent wet etching process, the etching rate on the <111> crystal plane orientation is faster than that on other crystal plane orientations.

As shown in FIG. 1C, a crystal orientation selective wet etching agent, such as, an etching agent containing TMAH, is used to etch the substrate in the U shaped recess to form a Sigma-shaped recess.

However, since the etching rates on the <100> crystal orientation and the <110> crystal orientation are faster than that on the <111>crystal orientation, the bottom of the recess is liable to be over etched, as a result, causing the lower portions of the opposite sidewalls of the recess to intersect. Thus, such anisotropic etching tends to cause a cuspate instead of a flat bottom. FIG. 2 shows a picture of Sigma shaped recesses in the prior art.

Besides, for current practices that apply wet etching after dry etching, serious micro loading effect on different CD regions is caused by the wet etching.

### BRIEF SUMMARY OF THE INVENTION

In view of the above problems, an object of the present invention is to provide a method of manufacturing semiconductor device, which can prevent the occurrence of a cuspate bottom during the formation of a Sigma shaped recess.

According to a first aspect of the present invention, there is provided a method for manufacturing semiconductor device, which may comprise: forming a recess in a substrate;

implanting at the bottom of the recess to form an amorphous layer to a predetermined depth under the bottom of the recess; carrying out orientation selective wet etching to form a Sigma shaped recess by use of the amorphous layer as a stopping layer.

Preferably, Ge, Si, BF₂, C, Xe, or Sb is adopted for the implantation.

Preferably, the implantation is carried out with an energy of 3˜10 KeV, a dosage of 5*10^{13˜5*10}¹⁵ atoms/cm², and an implant tilt angle of 0˜5 degree.

Preferably, the method further comprises: growing SiGe or SiGe:B (SiGe with in situ doped B) in the Sigma shaped recess.

Preferably, before growing SiGe or SiGe:B in the Sigma shaped recess, the method comprises: performing a heating treatment on the amorphous layer to facilitate the epitaxy growth of SiGe or SiGe:B, wherein, performing a heating treatment on the amorphous layer comprises: repairing the amorphous layer through spike anneal; or repairing the amorphous layer through SPER (Solid Phase Epitaxy regrowth); or repairing the amorphous layer through MSA (long pulse FLA or longer dwell time LSA). Preferably, the spike anneal is carried out at a temperature of 900˜1100° C.

Preferably, the semiconductor substrate has a gate formed thereon, and the Sigma shaped recess in which SiGe or SiGe:B is grown is used as a source/drain region.

Preferably, forming a recess in a substrate comprises: forming the recess in the substrate through dry etching.

According to a second aspect of the present invention, there is provided a semiconductor device, wherein the semiconductor device has a Sigma shaped recess formed on the surface of its substrate, and the bottom of the Sigma shaped recess is an amorphous layer.

Preferably, the material of the amorphous layer comprises Ge, Si, BF₂, C, Xe, or Sb.

Preferably, SiGe or SiGe:B is grown in the Sigma shaped recess.

Preferably, the semiconductor substrate of the semiconductor device has a gate formed thereon, and the Sigma shaped recess in which SiGe or SiGe:B is grown is used as source/drain region.

According to the method of manufacturing semiconductor device of the present invention, through forming an amorphous layer by implantation which is used as a stopping layer in a subsequent wet etching, a cuspate bottom of the obtained Sigma shaped recess can be prevented.

Further features of the present invention and advantages thereof will become apparent from the following detailed description of exemplary embodiments according to the present invention with reference to the attached drawings.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1A to FIG. 1C schematically show sectional views of various steps in a process of forming a sigma-shaped recess in the prior art.

FIG. 2 shows a picture of a Sigma shaped recess formed according to the prior art.

FIG. 3 is a flowchart showing a semiconductor device manufacturing method according to one embodiment of the present invention.

FIG. 4A to FIG. 4D schematically show sectional views of various steps in a semiconductor device manufacturing method according to one embodiment of the present invention.

FIG. 5A to FIG. 5F schematically show sectional views of various steps in a semiconductor device manufacturing method according to another embodiment of the present invention.

FIG. 6 shows a picture of a semiconductor device provided with a Sigma shaped recess.

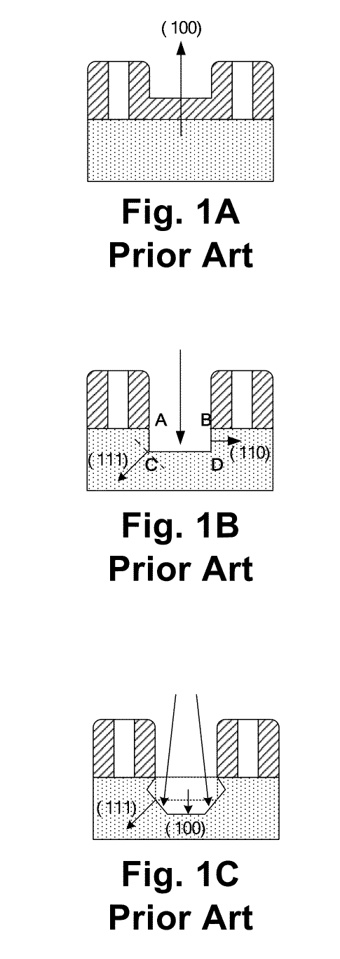

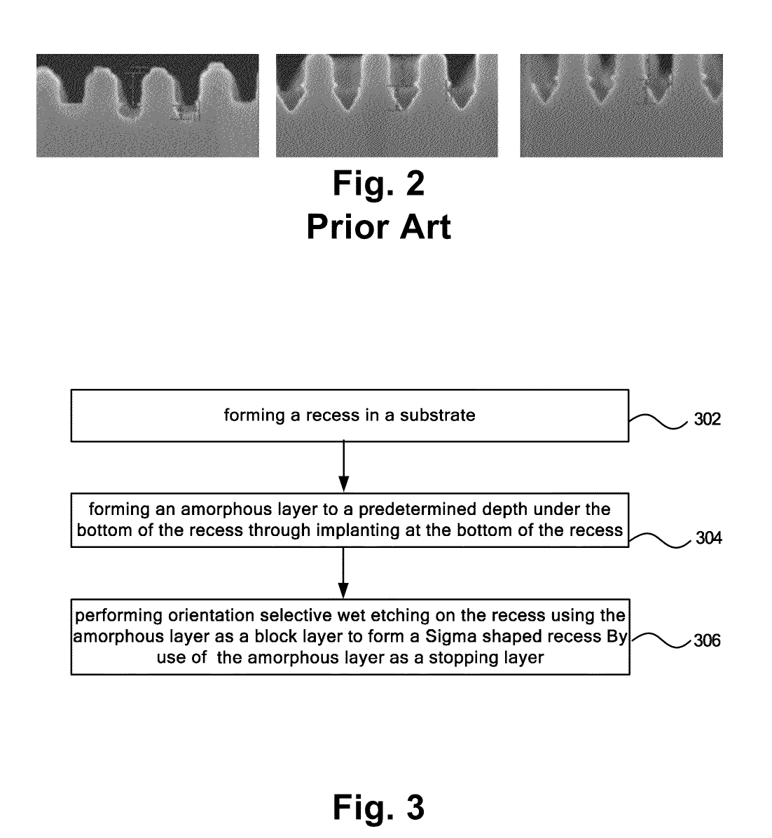

### DETAILED DESCRIPTION OF THE INVENTION

Various exemplary embodiments of the present invention will now be described in detail with reference to the drawings. It should be noted that the relative arrangement of the components and steps, the numerical expressions, and numerical values set forth in these embodiments do not limit the scope of the present invention unless it is specifically stated otherwise.

Also, it should be apparent that, for the convenience of description, various parts in these figures are not represented in scale.

The following description of at least one exemplary embodiment is merely illustrative in nature and is in no way intended to limit the invention, its application, or uses.

Techniques, methods and apparatus as known by one of ordinary skill in the relevant art may not be discussed in detail but are intended to be part of the specification where appropriate.

In all of the examples illustrated and discussed herein, any specific values should be interpreted to be illustrative only and non-limiting. Thus, other examples of the exemplary embodiments could have different values.

Notice that similar reference numerals and letters refer to similar items in the following figures, and thus, once an item is defined in one figure, it is possible that it need not be further discussed for following figures.

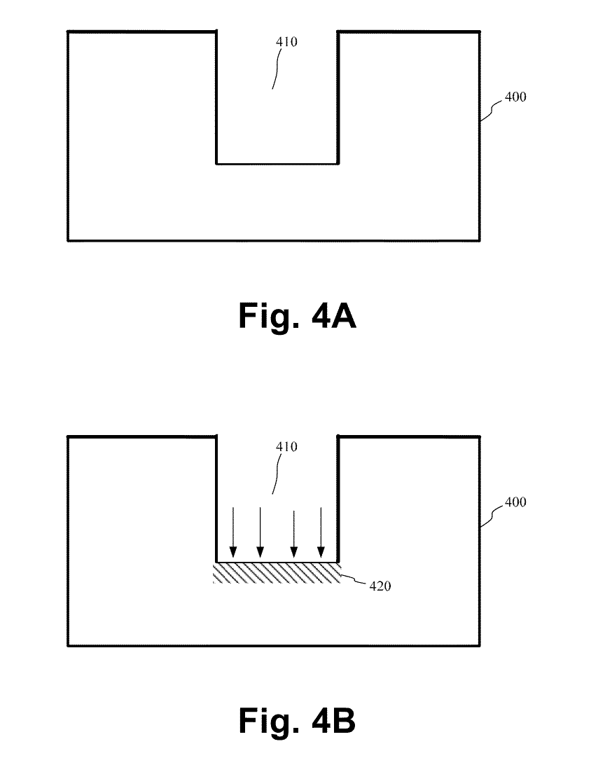

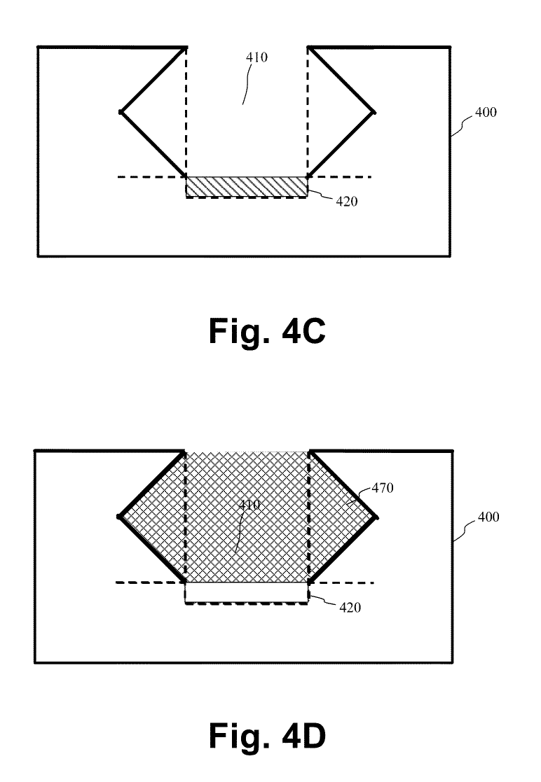

With reference to the flow chart shown in FIG. 3 and sectional views of various steps shown in FIGS. 4A to 4D, the method of manufacturing semiconductor device will be described below.

FIG. 3 is a flowchart showing a semiconductor device manufacturing method according to one embodiment of the present invention.

As show in FIG. 3, at step S302, a recess is formed in a substrate through, for example, dry etching.

The crystal plane orientation of the surface of the substrate may be (100). For example, as shown in FIG. 4A, a U shaped recess 410 is formed in a substrate 400. The material of the substrate 400 is, for example, silicon, and the U shaped recess 410 can be formed through any well known dry etching processes.

At step S304, An implantation is carried out at the bottom of the recess to form an amorphous layer to a predetermined depth under the bottom of the recess. Commonly, the amorphous layer extends from the bottom surface of the recess to a certain depth.

The depth of the amorphous layer can be determined by those skilled in the art depending on the design of source/drain regions, and the depth of the amorphous layer can be controlled through controlling implantation conditions. Ge, Si, BF₂, C, Xe, or Sb can be implanted as impurities. As shown in FIG. 4B, for example, pre-amorphous implantation (PAI) is carried out at the bottom of the recess 410 to form an amorphous layer 420 to a certain depth under bottom of the recess 410.

At step S306, crystal orientation selective wet etching is preformed on the recess by use of the amorphous layer as a stopping layer to form a Sigma shaped recess.

Common crystal orientation-selective wet etching in the art can be adopted. As shown in FIG. 4C, after crystal orientation-selective wet etching, Sigma shaped recess is formed in the semiconductor substrate 400, the bottom of the Sigma shaped recess is an amorphous layer 420 which can contain Ge, Si, BF₂, C, Xe, or Sb. The occurrence of a cuspate bottom of the sigma shaped recess can be avoided due to the amorphous layer acting as a stopping layer.

In the above embodiment, a Sigma shaped recess with a flat bottom can be obtained by means of forming an amorphous layer through implantation which acts as a stopping layer to the subsequent wet etching, and a Sigma shaped recess with a cuspate bottom can be avoided, allowing a Sigma shaped recess which may satisfy requirements of device performance and may further improve semiconductor device performance.

According to one embodiment of a semiconductor device manufacturing method of the present invention, implanting at the bottom of the recess to form an amorphous layer can be carried out under the following conditions: an implantation energy of 3˜10 KeV, a dosage of 5*10¹³˜5*10¹⁵ atoms/cm², and an implant tilt angle of 0˜5 degree. Through controlling the conditions of impurity implantation, the depth and distribution of the formed amorphous layer can be controlled.

According to one embodiment of a semiconductor device manufacturing method of the present invention, after forming the Sigma shaped recess, SiGe or SiGe:B can be grown in the

Sigma shaped recess. For example, SiGe or SiGe with in situ doped B (SiGe:B) can be grown at the bottom of the Sigma shaped recess 410 through epitaxy growth. FIG. 4D shows a diagram of the Sigma shaped recess 410 with SiGe or SiGe:B 470 grown in the recess 410. The Sigma shaped recess in which SiGe is grown can be used as the source/drain regions of the PMOS semiconductor device.

Optionally, a heating treatment is preformed on the amorphous layer before growing SiGe or SiGe:B in the Sigma shaped recess to have the amorphous layer recrystallized into monocrystal Si substrate, and thus facilitate the subsequent SiGe or SiGe:B growth. For example, the amorphous layer can be repaired through spike anneal at a temperature of, for example, 900˜1100° C.; or the amorphous layer can be repaired through SPER (Solid Phase Epitaxy Regrowth); or the amorphous layer can be repaired through MSA (Long Pulse FLA or Longer dwell time LSA). Through repairing the amorphous layer with a heating treatment, SiGe or SiGe:B can be better grown on the amorphous layer.

Generally, semiconductor devices, and among others, CMOS devices comprise both NMOS devices and PMOS devices.

Source/drain regions formed of embodied SiGe are usually used in PMOS devices. Therefore, before carrying out each step described next, the portions to form NMOS device should be shielded with a mask, so that only portions to be used for PMOS devices are provided with recesses and filled with embodied SiGe.

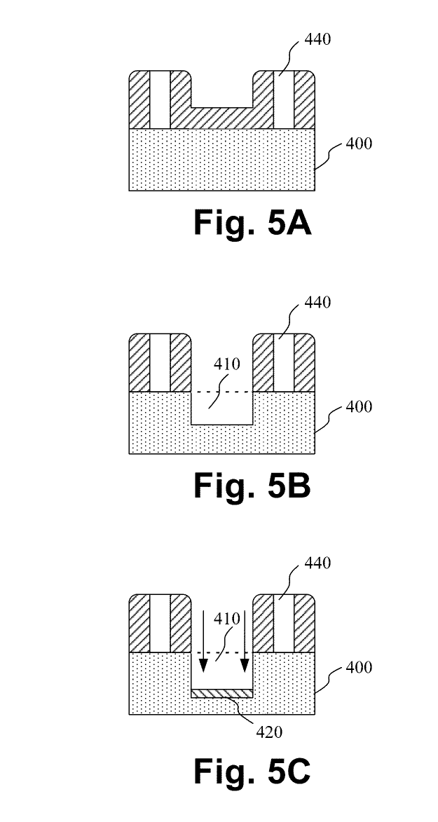

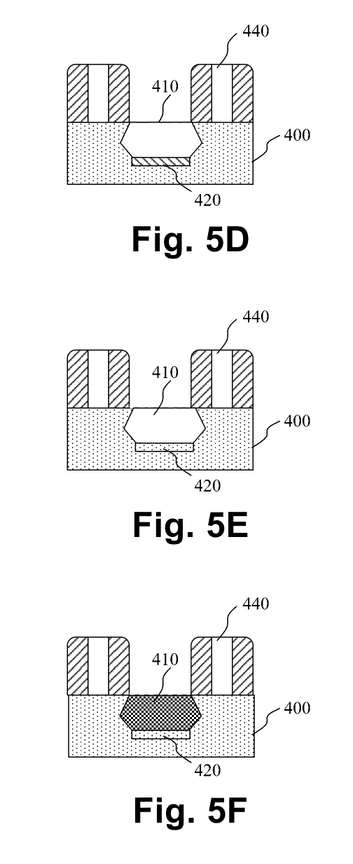

Next, another embodiment of the semiconductor device manufacturing method of the present invention will be introduced with reference to FIG. 5A to FIG. 5F.

As shown in FIG. 5A, a gate 440 is formed on a semiconductor substrate 400, and spacers can be formed on the opposite sides of the gate 440.

As shown in FIG. 5B, a recess 410 can be formed in a PMOS region of the semiconductor substrate 400 through dry etching, which is usually in a U shape.

As shown in FIG. 5C, pre-amorphous implantation (PAI) is carried out at the bottom of the recess 410 to form an amorphous layer 420 to a certain depth under bottom of the recess 410. Impurities that can be implanted are P-type impurities, such as Ge, Si, or BF₂.

As shown in FIG. 5D, crystal orientation selective wet etching is preformed on the recess 410 to the amorphous layer 420, which is used as a stopping layer in the wet etching, thereby a Sigma shaped recess 410 is formed.

As shown in FIG. 5E, the amorphous layer 420 at the bottom of the recess 410 is repaired through spike anneal, so that the amorphous layer 420 is recrystallized into monocrystal Si substrate to facilitate the subsequent SiGe or SiGe:B growth.

As shown in FIG. 5F, SiGe or SiGe:B is epitaxially grown in the Sigma shaped recess for acting as PMOS source/drain regions.

In the above embodiments, a Sigma shaped recess having a planar bottom is formed in a PMOS region through each of those process steps, and micro loading effect can be eliminated; SiGe or SiGe:B is epitaxially grown in the Sigma shaped recess for acting as PMOS source/drain regions, which increases the compress stress to the PMOS channel region, thus carrier mobility is enhanced, and semiconductor device performance is improved.

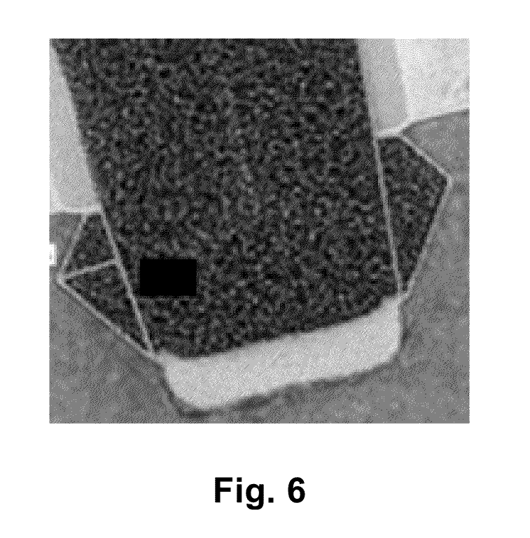

FIG. 6 shows a picture of the semiconductor device with a Sigma shaped recess. The bottom of the Sigma shaped recess 410 is the amorphous layer 420, and SiGe or SiGe:B epitaxial growth can be carried out in the Sigma shaped recess 410.

Thus, the semiconductor device and its manufacturing method of the present invention have been described in detail. Some specifics that are well known in the art are not provided in order not to obscure the ideas of the present invention. Those skilled in the art, according to the description above, may easily understand how to implement technical schemes disclosed herein.

The method and semiconductor device of the present invention can be implemented in many manners. The above described order of the steps for the method is only intended to be illustrative, and the steps of the method of the present invention are not limited to the above specifically described order unless otherwise specifically stated.

The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable those of ordinary skill in the art to understand the invention for various embodiments with various modifications as are suited to the particular use contemplated.

What is claimed is:

1. A method for manufacturing semiconductor device, the method comprising:
forming a recess in a substrate;
implanting at a bottom of the recess to form an amorphous layer to a predetermined depth under the bottom of the recess;
by use of the amorphous layer as a stopping layer, carrying out crystal orientation selective wet etching to form a Sigma shaped recess.

2. The method according to claim 1, characterized in that the implantation is carried out with Ge, Si, BF₂, C, Xe, or Sb.

3. The method according to claim 1, characterized in that the implantation is carried out with an energy of 3˜10 KeV, a dosage of 5*10¹³˜5*10¹⁵ atoms/cm², and an implant tilt angle of 0˜5 degree.

4. The method according to claim 1, characterized in further comprising:
growing SiGe or SiGe with in situ doped B in the Sigma shaped recess.

5. The method according to claim 4, characterized in that before growing SiGe or SiGe with in situ doped B in the Sigma shaped recess, the method comprises:
performing a heating treatment on the amorphous layer to facilitate the epitaxy growth of SiGe or SiGe with in situ doped B.

6. The method according to claim 5, characterized in that performing a heating treatment on the amorphous layer comprises:
repairing the amorphous layer through spike anneal; or
repairing the amorphous layer through Solid Phase Epitaxy regrowth (SPER); or
repairing the amorphous layer through long pulse FLA or longer dwell time LSA (MSA).

7. The method according to claim 6, characterized in that the spike anneal is carried out at a temperature of 900˜1100° C.

8. The method according to claim 4, characterized in that the semiconductor substrate has a gate formed thereon; and
the Sigma shaped recess in which SiGe or SiGe with in situ doped B is grown is used as source/drain region.

9. The method according to claim 1, characterized in that forming a recess in a substrate comprises:
forming the recess in the substrate through dry etching.

10. A semiconductor device, wherein the semiconductor device has a Sigma shaped recess formed in a substrate, and a bottom of the Sigma shaped recess is an amorphous layer.

11. The semiconductor device according to claim 10, characterized in that the material of the amorphous layer comprises Ge, Si, BF2, C, Xe, or Sb.

12. The semiconductor device according to claim 10, characterized in that SiGe or SiGe with in situ doped B is grown in the Sigma shaped recess.

13. The semiconductor device according to claim 12, characterized in that the semiconductor substrate of the semiconductor device has a gate formed thereon, and the Sigma shaped recess in which SiGe or SiGe with in situ doped B is grown is used as a source/drain region.
